(19) United States
(12) Patent Application Publication
(10) Pub. No.: US 2011/0262233 A1
(43) Pub. Date: Oct. 27, 2011

(54) COATED TOOL AND A METHOD OF MAKING THEREOF

(75) Inventor: Per Martensson, Nacka (SE)

(73) Assignee: SANDVIK INTELLECTUAL PROPERTY AB

(21) Appl. No.: 13/123,663

(22) PCT Filed: Oct. 9, 2009
(86) PCT No.: PCT/SE2009/051129

§ 371 Date: Apr. 18, 2011

(30) Foreign Application Priority Data
Oct. 30, 2008 (EP) 08167887.2

(51) Int. Cl. B23B 27/14; C23C 16/34

(52) U.S. Cl. 407/119; 427/255.15; 427/576

(57) ABSTRACT

The present invention relates to a tool for metal machining comprising a tool substrate of cemented carbide, cermet, ceramics or a super hard material, and a coating comprising an inner alumina layer and an outer titanium boronitride layer, wherein said layers are separated by one or more layers comprising an oxide layer other than an alumina layer, and a method of making the tool.

The present invention relates to a coated tool. More specifically, the invention pertains to a coated tool for metal machining with a hard and wear resistant coating comprising a layer of titanium boronitride.

### BACKGROUND OF THE INVENTION

Modern high productivity machining of metals requires reliable tools with high wear resistance, good toughness properties and excellent resistance to plastic deformation. The tools commonly comprise a tool substrate of, e.g., cemented carbide or cermet, onto which a suitable coating is applied. The coating is generally hard, wear resistant and stable at high temperatures, but quite often the demands on the different surfaces of a the tool vary. As an example, it is for a metal cutting tool in several cutting applications advantageous if the coating on the rake face, i.e., the face over which the chip flows, has a high chemical stability. The conditions at this face, characterized by high temperature and a constant transport of material over the face, causes diffusive elements to leave the coating via the chip, resulting in a rapid chemical wear. Alumina is known for its excellent chemical stability and is therefore commonly found as a component in cutting tool coatings. On the flank face of the tool, i.e., the face in contact with the work piece, the wear is of a more mechanical nature. Under such conditions a highly wear resistant coating is favourable, such as various nitrides, carbides and carbonitrides, particularly TiN, TiC and TiCN.

Even if desirable, it is not possible with today's large scale deposition techniques, such as chemical vapour deposition, to tailor-make the coatings on the separate faces of a tool by selectively depositing a layer on a single face of the tool. Instead, the same coating, including several functional layers deposited on top of each other in a layer stack, is deposited on all faces of the tool. Unfortunately, this limitation in the deposition techniques excludes desirable layer combinations including layers of wear resistant titanium boronitride, due to compatibility problems with other layer types, such as alumina.

EP 1 365 045 discloses a TiBN layer, particularly for cutter bodies, of a mixed phase consisting of TiN and TiB₂.

It is an object of the present invention to provide a method and a coating that alleviate the problems of the known technique.

It is a further object to provide a coated tool for metal machining having improved wear resistance.

### THE INVENTION

The present invention provides a tool for metal machining comprising a tool substrate of cemented carbide, cermet, ceramics or a super hard material, such as cubic boron nitride or diamond, preferably cemented carbide, and a coating comprising an inner alumina layer and an outer titanium boronitride layer wherein said layers are separated by one or more layers comprising an oxide layer other than an alumina layer.

The invention also provides a method of making the tool, comprising providing a tool substrate of cemented carbide, cermet, ceramics or a super hard material, preferably cemented carbide, and onto the substrate depositing a coating comprising an inner alumina layer, an oxide layer other than an alumina layer, and an outer titanium boronitride layer, using Chemical Vapour Deposition (CVD) or Plasma Assisted CVD (PACVD).

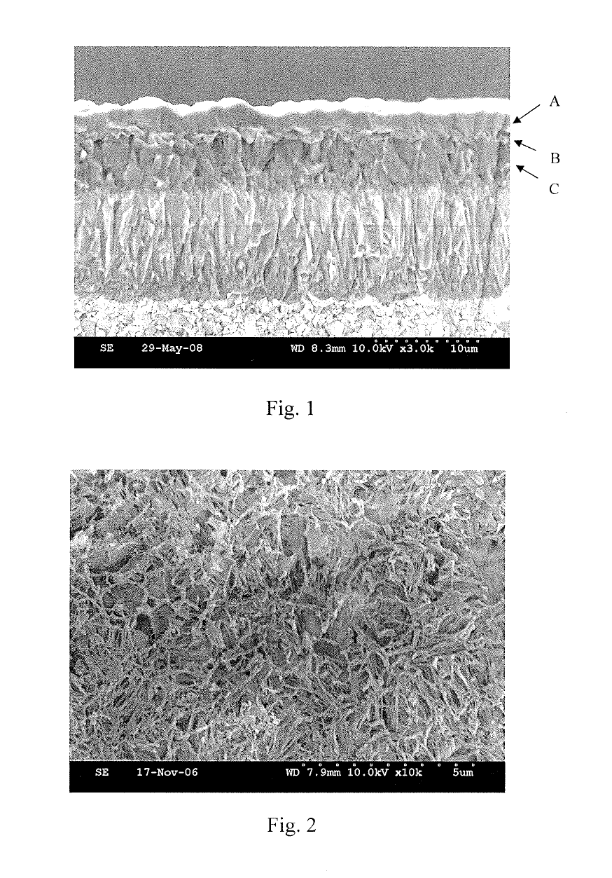

FIG. 1 shows a Scanning Electron Microscope (SEM) micrograph of an exemplary coated tool according to the present invention, in which

A) titanium boronitride layer

B) titanium oxide layer

C) alumina layer

FIG. 2 shows a top view SEM micrograph of a comparative coating including an alumina layer and a titanium boronitride layer.

The oxide layer separating the inner alumina layer and the outer titanium boronitride layer is suitably a thin layer of zirconium oxide, vanadium oxide, titanium oxide or hafnium oxide, preferably titanium oxide and zirconium oxide, most preferably titanium oxide, suitably having a thickness of 0.1 to 2 μm, preferably 0.5 to 1.5 μm, more preferably 0.5 to 1 μm.

The inner alumina layer is suitably of α-Al₂O₃, suitably having a thickness of 0.5 to 25 μm, preferably 2 to 19 μm, more preferably 3 to 15 μm.

The outer titanium boronitride layer is a composite of a mixture of TiB₂ phase and TiN phase, wherein the ratio TiB₂:TiN phase (atom-%) is suitably between 1:3 and 4:1, preferably 1:2 and 4:1, more preferably 1:1 and 4:1, most preferably 1:1 and 3:1. Suitably the thickness of this layer is 0.3 to 10 μm, preferably 0.5 to 7 μm, more preferably 0.5 to 6 μm.

In one embodiment, there is a TiN layer of a thickness of 0.1-1 μm between the oxide layer and the titanium boronitride layer, preferably applied directly on the oxide layer, and preferably the titanium boronitride layer applied directly on the TiN layer.

In one embodiment, the titanium boronitride layer is the outermost layer of the coating, and is suitably of a thickness of 0.3 to 2 μm, more preferably 0.5 to 1.5 μm. In this embodiment, the titanium boronitride layer has proven to have excellent properties as a wear detection layer, i.e., for detecting if a tool has already been used, particularly applied on a flank face of a metal cutting tool, due to the layers bright silver colour.

In one embodiment, the layers according to the invention are applied on top of a layer sequence comprising:
a first, 0.1 to 3 μm, preferably 0.3 to 2 μm, most preferably 0.5 to 1.5 μm, thick wear resistant layer sequence comprising one or several individual layers, the first layer being a transition metal compound being a carbide, nitride, oxide, carbonitride or carbooxynitride, preferably one of TiC, TiN, Ti(C,N), ZrN, HfN, most preferably TiN,
a second, 0.5 to 30 μm, preferably 3 to 20 μm, thick layer sequence comprising one or more layers of a transition metal compound being a nitride, carbide or carbonitride, preferably TiN, TiC, Ti(C,N), Zr(C,N), most preferably Ti(C,N) or Zr(C,N) with a columnar grain structure. The layer sequence may also comprise a Ti(C,N,O) layer having a plate like structure.

The total thickness of the coating is suitably >3.5 μm, preferably >5 μm, more preferably >7 μm, but suitably less than 30 μm, preferably less than 20 μm.

The tool is suitably a metal cutting tool for chip forming machining, such as turning, milling and drilling. The substrate is, thus, suitably in the shape of an insert for clamping in a tool holder, but can also be in the form of a solid drill or a milling cutter.

In the method, the inner alumina layer is suitably of α-Al₂O₃, deposited at a temperature of about 900 to 1050° C., and is suitably deposited to a thickness of 0.5 to 25 μm, preferably 2 to 19 μm, more preferably 3 to 15 μm.

Suitably the deposited oxide layer is of zirconium oxide, vanadium oxide, titanium oxide or hafnium oxide, more preferably titanium oxide and zirconium oxide, most preferably titanium oxide, deposited at a temperature of about 800 to 1050° C., and is suitably deposited to a thickness of 0.1 to 2 μm, preferably 0.5 to 1.5 μm, most preferably 0.5 to 1 μm.

The outer titanium boronitride layer, which is a composite of a mixture of TiB₂ phase and TiN phase, is suitably deposited to a TiB₂:TiN phase ratio between 1:3 and 4:1, preferably 1:2 and 4:1, more preferably 1:1 and 4:1, most preferably 1:1 and 3:1, by using a partial pressure ratio BCl₃:TiCl₄ in the gas mixture within the range of about 1:6 to 2:1, preferably 1:4 to 2:1, more preferably 1:2 to 2:1, most preferably 1:2 to 1.5:1.

Suitably the outer titanium boronitride layer is deposited at a temperature of about 700 to 900° C., and to a thickness of 0.3 to 10 μm, preferably 0.5 to 7 μm, more preferably 0.5 to 6 μm.

In one embodiment, the layers according to the invention are applied on top of a layer sequence comprising:
a first, 0.1 to 3 μm, preferably 0.3 to 2 μm, most preferably 0.5 to 1.5 μm, thick wear resistant layer sequence comprising one or several individual layers, the first layer being a transition metal compound being a carbide, nitride, oxide, carbonitride or carbooxynitride, preferably one of TiC, TiN, Ti(C,N), ZrN, HfN, most preferably TiN, at a temperature of about 850 to 1000° C.,
a second, 0.5 to 30 μm, preferably 3 to 20 μm, thick layer sequence comprising one or more layers of a transition metal compound being a nitride, carbide or carbonitride, preferably TiN, TiC, Ti(C,N), Zr(C,N), most preferably Ti(C,N) or Zr(C,N) with a columnar grain structure. The layer sequence may also comprise a Ti(C,N,O) layer having a plate like structure. The layer sequence is deposited at a temperature of about 800 to 1050° C.

### EXAMPLE 1

### Sample A

Cemented carbide inserts of ISO-type CNMG120408 for turning, consisting of 10 wt-% Co, 0.39 wt-% Cr and balance WC, were cleaned and subjected to a CVD coating process according to the following: The inserts were coated with an about 0.5 μm thick layer of TiN using conventional CVD-technique at 930° C. followed by an about 7 μm TiCₓN_{y} layer employing the MTCVD-technique using TiCl₄, H₂, N₂ and CH₃CN as process gases at a temperature of 885° C. In subsequent process steps during the same coating cycle a layer of TiCₓO_{z} about 0.5 μm thick was deposited at 1000° C. using TiCl₄, CO and H₂, and then an Al₂O₃-process (Al₂O₃-start) was started up by flushing the reactor with a mixture of 2 vol-% CO₂, 3.2 vol-% HCl and 94.8 vol-% H₂ for 2 min before an about 7 μm thick layer of α-Al₂O₃ was deposited. The process conditions during the deposition steps were as below:

TABLE 1
(concentration in vol-%)

| | TiN | TiCₓN_{y} | TiCₓO_{z} | Al₂O₃-start | Al₂O₃ |
|---|---|---|---|---|---|
| Step | 1 | 2 | 3 | 4 | 5 |
| TiCl₄ | 1.5 | 1.4 | 2 | | |
| N₂ | 38 | 38 | | | |
| CO₂: | | | | 2 | 4 |
| CO | | | 6 | | |
| AlCl₃: | | | | | 3.2 |
| H₂S | | | | | 0.3 |
| HCl | | | | 3.2 | 3.2 |
| H₂: | balance | balance | balance | balance | balance |
| CH₃CN | | 0.6 | | | |
| Pressure: | 160 mbar | 60 mbar | 60 mbar | 60 mbar | 70 mbar |
| Temp.: | 930° C. | 885° C. | 1000° C. | 1000° C. | 1000° C. |
| Time: | 30 min | 4.5 h | 20 min | 2 min | 4 h |

### Sample B1 (Invention)

Sample A inserts were subjected to a Ti₂O₃ deposition step, where the substrates to be coated were held at a temperature of 930° C. and were brought in contact with a hydrogen carrier gas containing TiCl₄ and CO₂. The nucleation was started up in a sequence where the reactant gas CO₂ entered the reactor first, in an H₂ atmosphere, followed by the TiCl₄. The titanium oxide layer was deposited to a thickness of about 0.75 μm thick with a CVD process using the following process parameters:

TABLE 2

| Concentration (in vol-%). | |
|---|---|
| T = 930° C., P = 55 mbar. | Ti₂O₃ |
| H₂ | 96.2 |
| CO₂ | 2.7 |
| TiCl₄ | 1.2 |
| Deposition Rate (μm/hrs) | 1.5 |

The inserts were subjected to a titanium boronitride (hereinafter denoted TiBN) deposition step, where the substrates to be coated were held at a temperature of 850° C. and were brought in contact with a hydrogen carrier gas containing N₂. The nucleation and growth was started up by the reactant gas TiCl₄ entering the reactor first, followed by the BCl₃. The TiBN layer was deposited to a thickness of about 2 μm with the following process parameters:

TABLE 3

| Concentration (in vol-%). | |
|---|---|
| T = 850° C., P = 55 mbar. | TiBN |
| H₂ | 59.4 |
| N₂ | 37.6 |
| BCl₃ | 1.5 |
| TiCl₄ | 1.5 |
| Deposition Rate (μm/hrs) | 1 |

Using microprobe measurement on a small angle polished cross section, with a Electron Microprobe Micro Analyser (EPMA) consisting of a Scanning Electron Microscope equipped with WDS, Jeol JXA-8900 R-WD/ED combined micro analyser, using a 10 kV acceleration voltage, the ratio TiB₂:TiN phase (atom-%) in the TiBN layer was determined to about 2:1. The ratio was calculated from the atomic concentration of the elements, obtained in the EPMA measurements.

### Sample B2 (Invention)

Sample A inserts were subjected to a ZrO₂ deposition step, where the substrates to be coated were held at a temperature of 1010° C. and were brought in contact with a hydrogen carrier gas containing ZrCl₄. The nucleation was started up in a sequence where the HCl entered the reactor first followed by the reactant gas CO₂, followed by the H₂S. The zirconium oxide layer was deposited to a thickness of about 2 μm thick with a CVD process using the following process parameters:

TABLE 4

| Concentration (in vol-%). | |
|---|---|
| T = 1010° C., P = 55 mbar. | ZrO₂ |
| H₂ | 90.3 |
| HCl | 5.9 |
| CO₂ | 2.3 |
| H₂S | 0.4 |
| ZrCl₄ | 1.1 |
| Deposition Rate (μm/hrs) | 1.3 |

Following the ZrO₂ deposition step the inserts were subjected to the same TiBN deposition process as the Sample B1 inserts (see Table 3).

### Sample C (Comparative)

Sample A inserts were subjected to a TiBN deposition process according to Table 4, depositing an about 3 μm thick TiBN layer directly onto the Al₂O₃ layer.

### Sample D (Comparative)

Sample A inserts were subjected to a deposition process according to Table 1, step 1, where a conventional about 0.5 μm thick TiN wear detection layer was deposited directly onto the Al₂O₃ layer.

### EXAMPLE 2

Samples B1, B2 and C were evaluated with regards to the adhesion of the different coatings, Table 5.

TABLE 5

| Sample | Adhesion of the TiBN layer |
|---|---|
| B1 (invention) | Good, FIG. 1 |
| B2 (invention) | Good |
| C (comparative) | Poor*, FIG. 2 |

*Excessive spontaneous flaking.

### EXAMPLE 3

Samples B1 and D were subjected to a standard blasting operation, whereby the outermost TiBN and TiN, respectively, layer was removed on the rake face of the inserts, using a mixture of water and alumina grains at a pressure of 2.4 bar. The appearance of the wear detection layer on the flank face, i.e., the face not exposed to the blasting media, after the blasting operation is found in Table 6.

TABLE 6

| | Appearance of the |
|---|---|
| Sample | wear detection layer |
| B1 (invention) | Excellent |
| D (comparative) | Good* |

*Some inserts showed minor, but unacceptable, marks on the flank faces caused by vibrations and grinding of blasting media trapped between inserts and the walls of the confinement.

Thus, the wear resistant titanium boronitride layer according to the invention, when used as an outermost layer, has a much better resistance to defects that occasionally occur during normal production steps, particularly blasting treatment, hence resulting in a better production yield.

1. A tool for metal machining comprising a tool substrate of cemented carbide, cermet, ceramics or a super hard material, and a coating comprising an inner alumina layer and an outer titanium boronitride layer, wherein said layers are separated by one or more layers comprising an oxide layer other than an alumina layer.

2. A tool according to claim 1 wherein the titanium boronitride layer has a ratio TiB2:TiN phase, atom-%, of between 1:3 and 4:1.

3. A tool according to claim 1 wherein the titanium boronitride layer has a ratio TiB2:TiN phase, atom-%, of between 1:1 and 4:1.

4. A tool according to claim 1, wherein the titanium boronitride layer is the outermost layer of the coating.

5. A tool according to claim 1, wherein the alumina layer is of α-Al₂O₃.

6. A tool according to claim 1, wherein the oxide layer is of zirconium oxide, vanadium oxide, titanium oxide or hafnium oxide.

7. A tool according to claim 1, wherein the oxide layer has a thickness of 0.1 to 2 μm.

8. A tool according to claim 1, wherein the tool substrate is of cemented carbide.

9. A tool according to claim 1, wherein the tool is a cutting tool insert.

10. A tool according to claim 1, wherein the tool is a solid drill, a milling cutter or a threading tap.

11. Method of making a tool for metal machining comprising providing a tool substrate of cemented carbide, cermet, ceramics or a super hard material, and onto the substrate depositing a coating comprising an inner alumina layer, an oxide layer other than an alumina layer, and an outer titanium boronitride layer by using Chemical Vapour Deposition or Plasma Assisted Chemical Vapour Deposition.

12. Method of making a tool according to claim 11 wherein depositing the titanium boronitride layer setting the partial pressure ratio BCl₃:TiCl₄ in the gas mixture within the range of 1:6 to 2:1.

13. Method of making a tool according to claim 11 wherein depositing the titanium boronitride layer using a partial pressure ratio BCl₃:TiCl₄ in the gas mixture within the range of 1:2 to 2:1.

14. Method of making a tool according to claim 11, wherein the deposited oxide layer is of zirconium oxide, vanadium oxide, titanium oxide or hafnium oxide.
